(19) United States
(12) Patent Application Publication
(10) Pub. No.: US 2008/0093658 A1
(43) Pub. Date: Apr. 24, 2008

(54) Method for Nitriding Tunnel Oxide Film, Method for Manufacturing Non-Volatile Memory Device, Non-Volatile Memory Device, Control Program and Computer-Readable Recording Medium

(75) Inventors: Toshihiko Shiozawa, Hyogo (JP); Shingo Furui, Osaka (JP); Takashi Kobayashi, Hyogo (JP); Junichi Kitagawa, Hyogo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/813,043

(22) PCT Filed: Dec. 22, 2005
(86) PCT No.: PCT/JP05/23597

§ 371 Date: Aug. 8, 2007

(30) Foreign Application Priority Data
Dec. 28, 2004 (JP) 2004-380705

(51) Int. Cl. H01L 29/788; H01L 21/383; H01L 21/8247

(52) U.S. Cl. 257/321; 438/513; 438/261; 257/E29.3; 257/E21.467; 257/E21.68

(57) ABSTRACT

When nitriding a tunnel oxide film in a nonvolatile memory device a nitrided region is formed in the surface portion of the tunnel oxide film by a plasma processing using a process gas containing nitrogen gas.

### FIELD OF THE INVENTION

The present invention relates to a method for nitriding a tunnel oxide film in a non-volatile memory device, a method for manufacturing a non-volatile memory device using the nitriding method, a non-volatile memory device, a control program to be used in executing the nitriding method and a computer-readable storage medium.

### BACKGROUND OF THE INVENTION

Conventionally, a nitriding process is performed on a tunnel oxide film in a non-volatile memory device such as an EPROM, an EEPROM, a flash memory and the like, to improve characteristics of the memory device. As the nitriding process for the oxide film, there has been conventionally known one implemented by a heat treatment (see, for example, Japanese Patent Laid-open Application Nos. H5-198573 and 2003-188291).

Since the conventional oxide film nitriding method by the heat treatment is performed in a thermal equilibrium state a location of a nitrided region and a nitrogen concentration of the nitrided region i.e., the nitrogen profile is substantially specified. Specifically, the location of the nitrided region is limited to an interface between the oxide film and a substrate, and an upper limit of the peak density of N becomes about 10²¹ atoms/cm³.

Recently, there is an increasing demand for the further improvement of a film quality of the tunnel oxide film, memory characteristics such as a data maintenance characteristic in a floating gate and the like. The conventional thermal nitriding process of the nitrogen profile as described above, however, does not satisfy such a demand.

### SUMMARY OF THE INVENTION

It is, therefore, an object of the present invention to provide a method for nitriding a tunnel oxide film of a nonvolatile memory device, capable of accomplishing a further improvement of a film quality of the tunnel oxide film, memory characteristics such as a data maintenance characteristic in a floating gate and the like.

It is another object of the present invention to provide a nonvolatile memory device manufactured by using the nitriding method and, also, to provide the manufacturing method.

It is still another object of the present invention to provide a control program to be used in executing the nitriding method and a computer-readable storage medium.

In accordance with a first aspect of the present invention, there is provided a method for nitriding a tunnel oxide film, including the steps of: preparing a substrate having a tunnel oxide film formed thereon; and forming a nitrided region at a surface portion of the tunnel oxide film by a plasma processing using a processing gas containing nitrogen gas.

In accordance with a second aspect of the present invention, there is provided a method for manufacturing a non-volatile memory device, including the steps of: forming a tunnel oxide film on a silicon substrate; forming a nitrided region at a surface portion of the tunnel oxide film by a plasma processing using a processing gas containing nitrogen gas; forming a floating gate on the tunnel oxide film; forming a dielectric film on the floating gate; forming a control gate on the dielectric film; and forming sidewall oxide films on sidewalls of the floating gate and the control gate.

In accordance with a third aspect of the present invention, there is provided a non-volatile memory device including: a silicon substrate; a tunnel oxide film formed on the silicon substrate; a floating gate formed on the tunnel oxide film; a dielectric film formed on the floating gate; a control gate formed on the dielectric film; and sidewall oxide films formed on sidewalls of the floating gate and the control gate, wherein the tunnel oxide film has a nitrided region formed by a plasma processing using a processing gas containing nitrogen gas.

In accordance with a fourth aspect of the present invention, there is provided a computer-executable control program for controlling, when executed, a plasma processing apparatus to perform a method for nitriding a tunnel oxide film which includes the steps of: preparing a substrate having a tunnel oxide film formed thereon to form a non-volatile memory device; and forming a nitrided region at a surface portion of the tunnel oxide film by a plasma processing using a processing gas containing nitrogen gas.

In accordance with a fifth aspect of the present invention, there is provided a computer-readable storage medium for storing therein a computer-executable control program, wherein the control program controls, when executed, a plasma processing apparatus to perform a method for nitriding a tunnel oxide film which includes the steps of: preparing a substrate having a tunnel oxide film formed thereon to form a non-volatile memory device; and forming a nitrided region at a surface portion of the tunnel oxide film by a plasma processing using a processing gas containing nitrogen gas.

In the first and the second aspect of the present invention, it is preferred that the plasma processing is performed by using a plasma processing apparatus which generates a plasma by introducing a microwave into a processing chamber by means of a planar antenna provided with a plurality of slots. Further, it is also preferred that the processing gas contains a rare gas, and the rare gas is preferably Ar gas. Preferably, an N dose of the nitrided region is equal to or greater than about 1×10¹⁵ atoms/cm². Moreover, it is preferred that the plasma processing is performed at a pressure of about 6.7 to 266 Pa.

In the third aspect of the present invention, the nitrided region is formed by using a plasma processing apparatus which generates a plasma by introducing a microwave into a processing chamber by means of a planar antenna provided with a plurality of slots. Further, it is also preferred that the processing gas contains a rare gas, and the rare gas is preferably Ar gas. Preferably, an N dose of the nitrided region is equal to or greater than about 1×10¹⁵ atoms/cm².

In accordance with the present invention, since the tunnel oxide film is formed by the plasma processing using the processing gas containing the nitrogen gas, flexibility of nitrogen profile can be improved, compared to a conventional nitriding process by a heat treatment. Therefore, it is possible to form, at the surface portion of the tunnel oxide film, the nitrided region having a nitrogen concentration higher than that obtained by the heat treatment. Thus, trap sites present at the surface portion of the tunnel oxide film can be terminated with nitrogen, so that traps generated in the tunnel oxide film due to a memory operation can be reduced, and the quality of the tunnel oxide film can be maintained fine. Further, when forming the sidewall oxide films, the nitrided region functions as a barrier against an oxidizing agent, so that a defective oxidation (bird's beak) can be prevented at an interface end portion between the floating gate and the tunnel oxide film, and a data maintenance characteristic can be improved. Moreover, since the nitrided region having a high dielectric constant is formed at the surface portion of the tunnel oxide film, the equivalent oxide thickness (EOT) of SiO₂ can be reduced without changing the interface state, whereby it is possible to improve the data maintenance characteristic without changing an interface characteristic. If the EOT is maintained same, the tunnel oxide film can be made thicker instead, so that a leakage current can be suppressed as much as the thickness of the tunnel oxide film increases. As a result, the data maintenance characteristic can be improved as expected.

### BRIEF DESCRIPTION OF THE DRAWINGS

FIG. 1A provides a diagram for describing an example of a process of a nitriding method for a tunnel oxide film in accordance with the present invention.

FIG. 1B still sets forth a diagram for describing the exemplary process of the nitriding method for the tunnel oxide film in accordance with the present invention.

FIG. 2 provides a cross sectional view showing an example of a memory cell of a non-volatile memory device fabricated by using the nitriding method in accordance with the present invention.

FIG. 3 presents a schematic cross sectional view showing an example of a plasma processing apparatus for performing the nitriding method for a tunnel oxide film in accordance with the present invention.

FIG. 4 depicts a diagram showing a structure of a planar antenna used in the microwave plasma apparatus shown in FIG. 3.

FIG. 5 offers a flowchart for describing a sequence of a nitriding process.

FIG. 6A is a graph showing a nitrogen profile of a thermal oxide film after performing a thermal nitriding process.

FIG. 6B is a graph showing a nitrogen profile of a thermal oxide film after performing a plasma nitriding process.

FIG. 7 provides a graph showing a nitrogen concentration distribution of the tunnel oxide film when the plasma nitriding process is performed.

FIG. 8A sets forth a schematic diagram for describing a state in which traps are generated in the tunnel oxide film due to a memory operation in a conventional case.

FIG. 8B provides a schematic diagram for describing an effect of preventing a generation of traps in the tunnel oxide film, which is exerted by a nitriding method for a tunnel oxide film in accordance with an embodiment of the present invention.

FIG. 9A presents a diagram for describing a state in which a bird's beak is generated by a conventional nitriding method for a tunnel oxide film.

FIG. 9B shows a diagram for describing a birds beak prevention effect exerted by the nitriding method for the tunnel oxide film in accordance with the embodiment of the present invention.

FIG. 10 is a diagram showing a relationship between a leakage current Jg (A/cm²) and an electric field E_{OX} (MV/cm) applied in a thickness direction, with respect to a base oxide film without being nitrided and cases where the nitriding process in accordance with the embodiment of the present invention is performed thereon while varying a dose of nitrogen.

FIG. 11 is a diagram showing a FN plot, with respect to a base oxide film without being nitrided and cases where the nitriding process in accordance with the embodiment of the present invention is performed thereon while varying a dose of nitrogen.

FIG. 12 is a diagram showing a relationship between a flat band voltage (Vfb) and an EOT of a tunnel oxide film, with respect to a base oxide film without being nitrided and cases where the nitriding process in accordance with the embodiment of the present invention is performed thereon while varying a dose of nitrogen.

### DETAILED DESCRIPTION OF THE EMBODIMENTS

Hereinafter, an embodiment of the present invention will be described in detail with reference to the accompanying drawings.

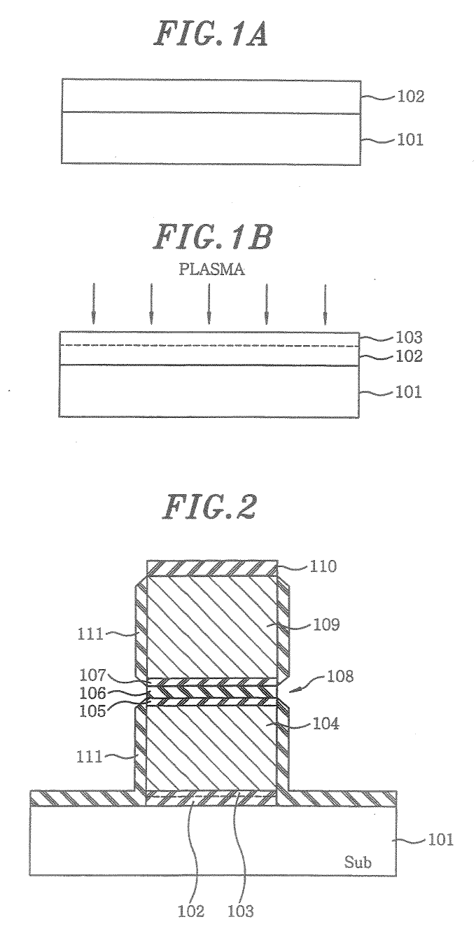

FIGS. 1A and 1B are cross sectional views for describing a method for nitriding a tunnel oxide film in accordance with the present invention which is performed in the part of manufacturing a non-volatile memory device such as an EPROM, an EEPROM, a flash memory, and so forth in a manufacturing process of a memory cell of a non-volatile memory device, a tunnel oxide film 102 is first formed on a main surface of a Si substrate 101 in a thickness of about 10 nm through e.g., a thermal oxidation process of the Si substrate 101, as shown in FIG. 1A. Then, an ion implantation is performed on the main surface area of the Si substrate 101 and, subsequently a nitriding process of the tunnel oxide film 102 is carried out. The nitriding process is performed by a plasma processing of a gas containing nitrogen gas. As a result of the nitriding process, a nitrided region 103 is formed at a surface portion of the tunnel oxide film 1021 as illustrated in FIG. 1B.

By carrying out the nitriding process by the plasma processing as described above, it is possible to control a nitrogen profile in the tunnel oxide film 102 unlike in a conventional nitriding process of an oxide film by a heat treatment, so that the nitrided region 103 having a high nitrogen concentration can be formed at the surface portion of the tunnel oxide film 102. Specifically, the nitrided region 103 can be formed at the outermost surface portion of the tunnel oxide film 102 ranging from the top surface of the tunnel oxide film 102 to a depth of about 2 nm or less therefrom.

After the nitriding process, by performing subsequent processes according to a conventional method, a nonvolatile memory device having a memory cell with a structure schematically illustrated in FIG. 2 is obtained. That is, the structure of the memory cell is as follows: the tunnel oxide film 102 having the nitrided region 103 at its surface portion is formed on the main surface of the Si substrate 101; a floating gate electrode 104 made of polysilicon is formed on the tunnel oxide film 102; a dielectric film 108 with an ONO structure made up of, e.g., an oxide film 105, a nitride film 106 and an oxide film 107 is formed on the floating gate electrode 104; a control gate electrode 109 made of polysilicon or a multi-layered film of, e.g., polysilicon and tungsten silicide is formed on the dielectric film 6 an insulating layer 110 protection film) formed of Si₃N₄, SiO₂ or the like is formed on the control gate electrode 109; and sidewall oxide films 111 are formed on the sidewalls of the floating gate electrode 104 and the control gate electrode 109 by oxidizing the surface thereof.

The subsequent processes following the nitriding process are schematically exemplified as follows.

A polysilicon film to be used as the floating gate electrode 104 is formed on the tunnel oxide film 102 which has undergone the plasma nitriding process. Then, an oxide film, a nitride film and an oxide film are successively formed on the polysilicon film and a polysilicon film or a multi-layered film of e.g., polysilicon and tungsten silicide which becomes the control gate electrode 109 is formed on the resultant structure. Here, the film formations are performed by, e.g. CVD.

Thereafter, dry etching by plasma is performed by using a photoresist layer (not shown) and a hard mask layer as a mask, whereby the floating gate electrode 104, the ONO-structured dielectric film 108, and the control gate electrode 109 are formed. Thereafter, an oxidation process is performed on portions of the floating gate electrode 104 and the control gate electrode 109 where the polysilicon is exposed, whereby the sidewall oxide films 111 are formed thereon. As the oxidation process, a plasma processing using a gas containing oxygen gas is more preferable to form fine oxide films without oxidizing the tungsten than a thermal oxidation process such as a wet method using a water vapor generator or a dry method using O₂ gas. Among various types of plasma processings, a plasma processing of a RLSA (radial line slot antenna) microwave plasma type, which is to be described later, is particularly preferable, because it enables a low-temperature processing at a low electron temperature with a high-density plasma.

Through the above-described process, a non-volatile memory device with the memory cell having the structure shown in FIG. 2 is formed.

Now, a preferred embodiment of the above-described nitriding process will be explained.

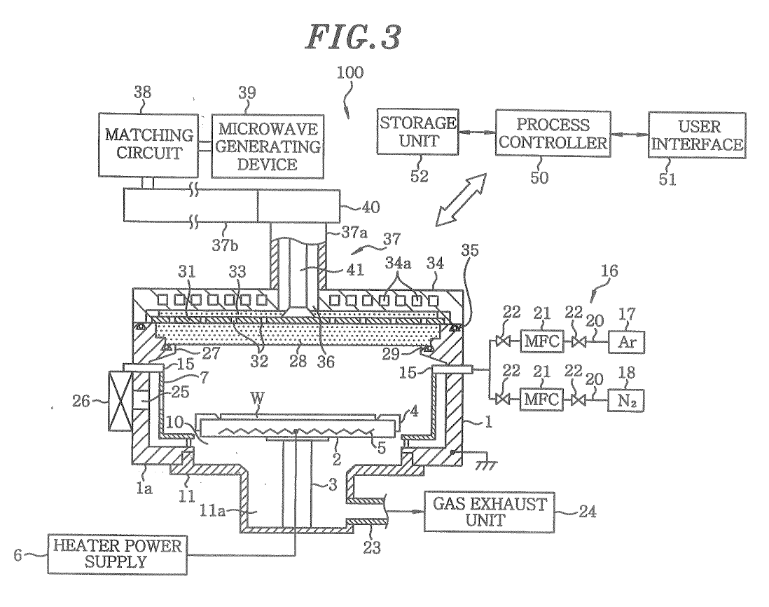

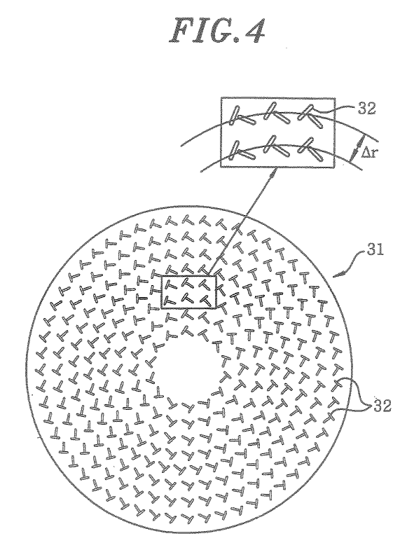

FIG. 3 is a cross sectional view showing an example of a plasma processing apparatus for performing the nitriding method for a tunnel oxide film in accordance with the present invention.

The plasma processing apparatus 100 is configured as a RLSA microwave plasma processing apparatus which generates plasma by radiating a microwave induced from a microwave generator into a chamber by using a planar radial line slot antenna provided with a multiplicity of slots arranged in a specific pattern.

The plasma processing apparatus 100 includes a substantially cylindrical chamber 1 which is airtightly sealed and grounded. A circular opening 10 is provided at a substantially central portion of a bottom wall 1a of the chamber 1, and a gas exhaust chamber 11 communicating with the opening 10 is provided at the bottom wall 1a in a manner that it protrudes downward. A susceptor 2 made of ceramic, e.g., AlN, is disposed in the chamber 1 to horizontally support thereon a Si wafer W, which is a substrate to be processed. The susceptor 2 is supported by a cylindrical supporting member 3 made of ceramic, e.g., AlN, and extending upward from a central bottom portion of the gas exhaust chamber 11. A guide ring 4 for guiding the Si wafer W is disposed on the outer periphery portion of the susceptor 2. Further, a resistance heater 5 is embedded in the susceptor 2 to heat the susceptor 2 by a power supplied from a heater power supply 6, and the Si wafer W to be processed is heated by the heated susceptor 2. Here, the temperature of the wafer W can be controlled in a range from, e.g., a room temperature to about 800° C. Further, a cylindrical liner 7 made of a dielectric material e.g., quartz is provided on an inner periphery of the chamber 1.

The susceptor 2 is provided with wafer supporting pins (not shown) which serve to support the wafer W, while moving up and down the wafer W, wherein the wafer supporting pins are configured to be protrusible above and retractable below the surface of the susceptor 2.

A ring shaped gas introducing member 15 is provided on a sidewall of the chamber 1, and a gas supply system 16 is connected to the gas introducing member 15. The gas introducing member may be disposed in a shower shape. The gas supply system 16 includes an Ar gas supply source 17 and an N₂ gas supply source 18, and these gases are supplied to the gas introducing member 15 through respective gas lines 20 to be introduced into the chamber 1 through the gas introducing member 15. Each of the gas lines 20 is provided with a mass flow controller 21 and opening/closing valves 22 disposed at an upstream and a downstream side of the mass flow controller 21.

A gas exhaust line 23 is connected to a side surface of the exhaust chamber 11, and a gas exhaust unit 24 having a high speed vacuum pump is connected to the gas exhaust line 23. By operating the gas exhaust unit 24, a gas in the chamber 1 is uniformly discharged into a space 11a of the exhaust chamber 11 to be exhausted outside through the gas exhaust line 23. Accordingly, the inside of the chamber 1 can be depressurized to a predetermined vacuum level, e.g., about 0.133 Pa, at a high speed.

At the sidewall of the chamber 1, there are provided a loading/unloading port 25 through which the wafer W is transferred between the chamber 1 and a transfer chamber (not shown) disposed adjacent to the plasma processing apparatus 100; and a gate valve 26 for opening and closing the loading/unloading port 25.

The chamber 1 has an opening at its top, and a ring shaped support 27 is provided along the circumference of the opening. A microwave transmitting plate 28 made of a dielectric material, e.g., quartz or ceramic such as Al₂O₃ or the like, is airtightly disposed on the support 27 via a seal member 29. Accordingly, the inside of the chamber 1 is hermetically kept.

A circular plate shaped planar antenna member 31 is provided on the microwave transmitting plate 28 to face the susceptor 2. The planar antenna member 31 is held by a top end of the support 27. The planar antenna member 31 is made of a conductor, e.g., aluminum plate or copper plate plated with gold or silver, and it is provided with a plurality of microwave radiation holes 32 formed therethrough in a certain pattern. Each microwave radiation hole 32 is formed in, e.g., an elongated groove shape as shown in FIG. 4, and the adjacent microwave radiation holes 32 are arranged to cross each other, typically in a perpendicular manner (in a T-shape), as shown in FIG. 4. These microwave radiation holes 32 are concentrically arranged. That is, the planar antenna member 31 is configured as a RLSA antenna. The length of each microwave radiation hole 32 and an arrangement interval between the microwave radiation holes 32 are determined depending on a wavelength λ of the microwave. For example, the microwave radiation holes 32 are disposed at an interval of ½λ or λ=Further, the microwave radiation holes 32 may be formed in different shapes such as a circular shape, an arc shape and the like. Further, the arrangement pattern of the microwave radiation holes 32 is not limited to the concentric circular pattern exemplified herein but they may be disposed in, e.g., a spiral shape, a radial shape or the like.

On a top surface of the planar antenna member 31, there is disposed a retardation member 33 formed of a dielectric material having a dielectric constant greater than that of a vacuum.

On a top surface of the chamber 1, a shield cover 34 made of a metal material, e.g., aluminum, stainless steel or the like, is provided to cover the planar antenna member 31 and the retardation member 33. A seal member 35 seals between the top surface of the chamber 1 and the shield cover 34. Further, a cooling water path 34a is formed in the shield cover 34, and the shield cover 34 is grounded.

The shield cover 34 has an opening 36 in a center of its top wall, and a waveguide 37 is connected to the opening. A microwave generating device 39 is connected to an end portion of the waveguide 37 via a matching circuit 38, whereby a microwave having a frequency of, e.g., about 2.45 GHz generated from the microwave generating device 39 is allowed to propagate to the planar antenna member 31 through the waveguide 37. Here, a microwave having a frequency of about 8.35 GHz or about 1.98 GHz may be used.

The waveguide 37 includes a coaxial waveguide 37a having a circular cross section and extending upward from the opening 36 of the shield cover 34; and a rectangular waveguide 37b having a rectangular cross section and extending in a horizontal direction. A mode transducer 40 is disposed between them. Further, an internal conductor 41 extends in the coaxial waveguide 37a, and a lower end of the internal conductor 41 is fixedly connected to the center of the planar antenna member 31.

Each component of the plasma processing apparatus 100 is connected to and controlled by a process controller 50. A user interface 51 is connected to the process controller 50, wherein the user interface 51 includes, e.g., a keyboard for a process manager to input a command to operate the plasma processing apparatus 100, a display for showing an operational status of the plasma processing apparatus 100, and the like.

Moreover, connected to the process controller 50 is a storage unit 52 for storing therein control programs for implementing various processes, which are performed in the plasma processing apparatus 100 under the control of the process controller 50, and programs or recipes to be used in carrying out the various processes by each component of the plasma etching apparatus according to processing conditions. The recipes can be stored in a hard disk or a semiconductor memory, or can be set at a certain position of the storage unit 52 while being recorded on a portable storage medium such as a CDROM, a DVD and the like. Alternatively, the recipes can be transmitted from another apparatus via, e.g., a dedicated line.

When a command is received from the user interface 51, the process controller 50 retrieves and executes a necessary recipe from the storage unit 52, and a desired process is performed in the plasma processing apparatus 100 under the control of the process controller 50.

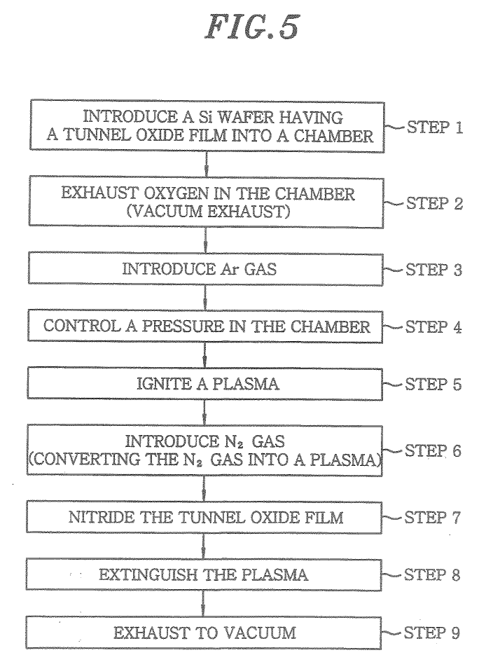

Hereinafter, a plasma nitriding process, which is performed by the plasma processing apparatus 100 configured as describe above, will be explained with reference to a flowchart of FIG. 5.

First, the gate valve 26 is opened, and a Si wafer W having a tunnel oxide film previously formed thereon is loaded into the chamber 1 through the loading/unloading port 25 and mounted on the susceptor 2 (step 1). The tunnel oxide film is formed in a thickness of about 3.5 to 15 nm through a thermal oxidation process of a wet type using a water vapor generator or a dry type using O₂ gas. Typically, the tunnel oxide film is formed in a thickness of about 10 nm.

Subsequently, to remove oxygen from the inside of the chamber 1, the chamber 1 is vacuum exhausted (step 2), and Ar gas is supplied at a specific flow rate into the chamber 1 from the Ar gas supply source 17 via the gas introducing member 15 (step 3). By controlling the internal pressure of the chamber 1 by means of adjusting the flow rate of the Ar gas, the inside of the chamber is kept in a high pressure state in which plasma ignition readily occurs (step 4). Here, the pressure level is preferably set to be in a range from about 13.3 to 267 Pa and, for example, is set to about 66.6 Pa or 126 Pa. Further, the internal pressure in this process is set to be higher than that in a nitriding process to be described later.

Thereafter, a plasma ignition is carried out by radiating a microwave into the chamber 1 (step 5). At this time, the microwave from the microwave generating device 39 is first directed to the waveguide 37 via the matching circuit 38. The microwave propagates through the rectangular waveguide 37b, the mode transducer 40 and the coaxial waveguide 37a subsequently, and then reaches the planar antenna member 31. Then, the microwave is radiated into a space above the wafer W in the chamber 1 from the planar antenna member 31 via the microwave transmitting plate 28. In the chamber 1, the Ar gas is converted into plasma by the microwave thus radiated into the chamber 1. At this time, the power level of the microwave is preferably set to be in a range from about 1000 to 3000 W and is set to about 1600 W for example. After the plasma ignition, the internal pressure of the chamber 1 is regulated at, e.g., about 6.7 Pa.

After the plasma ignition, N₂ gas is introduced at a specific flow rate into the chamber 1 from the N₂ gas supply source 18 of the gas supply system 16 via the gas introducing member 15. The N₂ gas is also converted into plasma by the microwave radiated into the chamber (step 6).

By the plasma of the Ar gas and the N₂ gas so generated, a nitriding process is performed on the tunnel oxide film formed on the Si wafer W (step 7). At this time, a pressure level is preferably set to be in a range from about 1.3 to 266 Pa, and is set to 126 Pa for example. Further a processing temperature is preferably set to be in a range from about 200 to 600° C. and is set to 400° C. for example. Further, the flow rate of the Ar gas preferably ranges from about 250 to 3000 mL/min (sccm), and the flow rate of the N₂ gas preferably ranges from about 10 to 300 mL/min (sccm). For example, the flow rates of the Ar and the N₂ gas are 1000 mL/min (sccm) and 40 mL/min (sccm), respectively. Further, a flow rate ratio between the Ar gas and the N₂ gas (Ar/N₂) is preferably set to range from about 1.6 to 300 and, more preferably, from about 10 to 100. Moreover, a processing time is preferably set to be about 30 to 600 sec and is set to 240 sec for example. By performing the nitriding process under the above-exemplified conditions, the dose of N becomes about 5.0×10¹⁵ atoms/cm².

After performing the nitriding process for the predetermined time as described above, the radiation of the microwave is stopped to extinguish the plasma (step 8), and the supply of the gases is stopped while the vacuum exhaust of the chamber is being performed (step 9). So, the sequence of the nitriding process is finished.

In the above process, though the Ar gas is first supplied and the N₂ gas is then supplied after igniting the plasma, the Ar gas and the N₂ gas may be simultaneously supplied and the plasma may be ignited thereafter, as long as the plasma ignition is feasible.

The microwave plasma described above is a low electron temperature plasma of about 0.5 to 1.5 eV having a plasma concentration of about 10¹¹/cm³ or greater. With this microwave plasma, it is possible, through the low-temperature and the short-period processing as described above, to form a nitrided region having a high nitrogen concentration at a surface portion of the tunnel oxide film, specifically, at an outermost surface portion of the tunnel oxide film ranging from its top surface to a depth of about 2 nm therefrom. Further, the microwave plasma also has a merit in that a plasma damage that might be caused by, e.g., an ion impact on an underlying film is reduced. Furthermore, since the nitriding process is performed at a low temperature by the high-density plasma for a short period of time, a nitrogen profile of the nitrided region can be controlled to be of a high density.

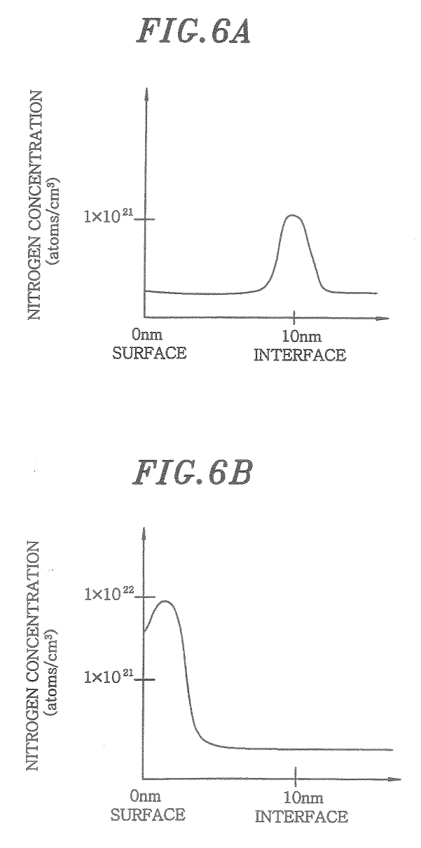

As for a thermal nitriding process, since the thermal nitriding process is performed in a thermal equilibrium state, the location of the nitrided region is limited to an interface between the tunnel oxide film and the substrate, as illustrated in FIG. 6A, and the peak concentration of nitrogen atoms is delimited to about 10²¹ atoms/cm³. In contrast, when the plasma nitriding process in accordance with this embodiment is employed, a nitrided region having a high nitrogen concentration (10²² atoms/cm³ in this example) can be formed at the outermost surface portion of the tunnel oxide film ranging from its top surface to the depth of about 2 nm therefrom, as shown in FIG. 6. On the other hand, it is also possible to form a region where nitrogen hardly exists, at the interface between the tunnel oxide film and the substrate. The nitrogen concentration can be appropriately controlled depending on processing conditions and the location of the nitrided region can also be appropriately controlled in a spatial range from the top surface of the tunnel oxide film to the depth of about 2 nm therefrom by way of adjusting the processing conditions.

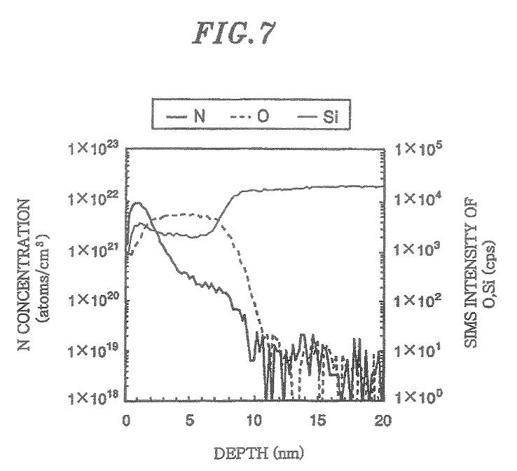

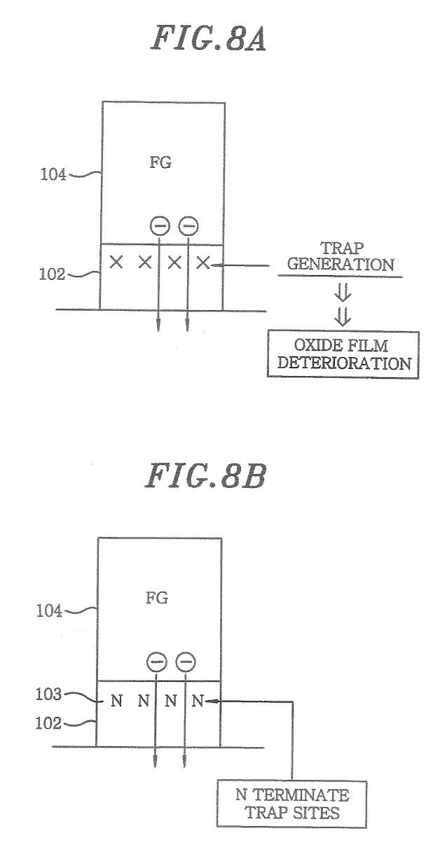

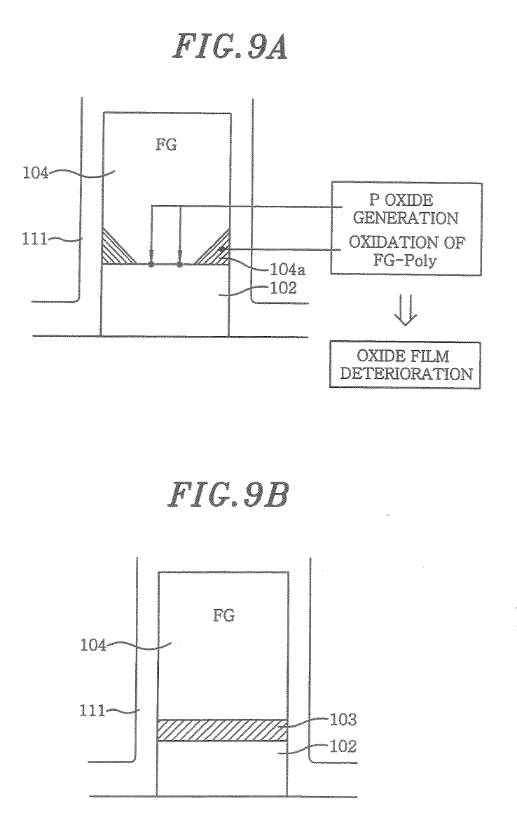

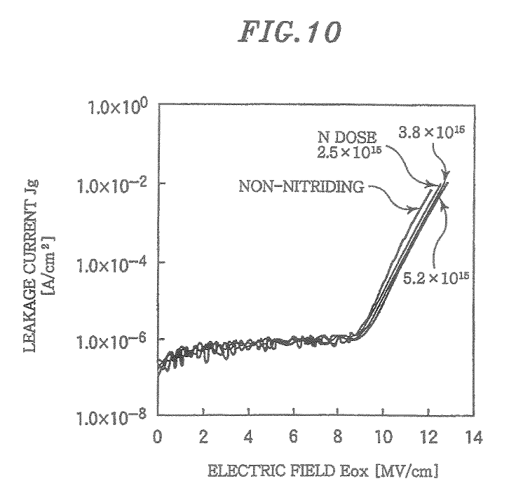

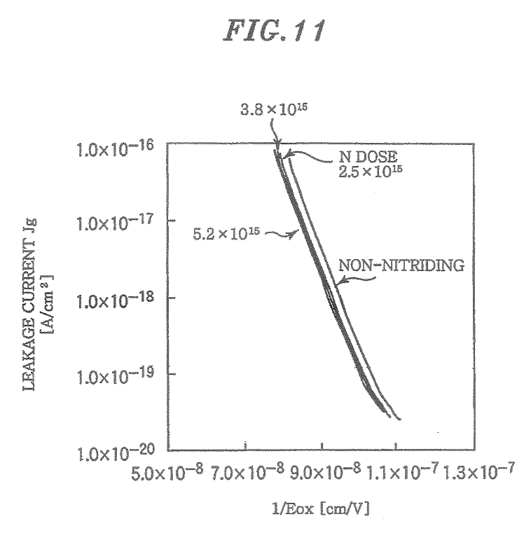

FIG. 7 shows a nitrogen concentration distribution, which is based on SIMS measurement results in case of performing a nitriding process in accordance with the method of the present invention. In FIG. 7, SIMS (Secondary Ion Mass Spectrometry) intensity distributions of O and Si are also presented. In this experiment a nitriding process was performed by using the apparatus shown in FIG. 3 under processing conditions as follows: the internal pressure of the chamber was 126 Pa, the microwave power was 1600 W, and the flow rates of Ar and N₂ were 1000 mL/min (sccm) and 40 mL/min (sccm), respectively. Further, the thickness of the tunnel oxide film was 10 nm. As shown in this figure, it is confirmed that the nitrogen concentration reaches a peak at a location about 1 nm down from the top surface of the tunnel oxide film.

As described above, since it is possible to form the high-concentration nitrided region at the surface of the tunnel oxide film and, also, to form the region where no nitrogen exists, at the interface between the tunnel oxide film and the substrate, a generation of traps, which might be caused in the tunnel oxide film by a memory operation, can be prevented. That is, in conventional cases, traps are generated in the tunnel oxide film 102 due to the memory operation, as shown in FIG. 5A. However, by forming the nitrided region 103 at the surface portion of the tunnel oxide film 102 through the plasma nitriding process, the trap sites are terminated with nitrogen atoms, as shown in FIG. 5E, so that the generation of the traps can be reduced, a23 and the quality of the tunnel oxide film can be maintained fine. Moreover, there is no Vt (a shift of switching voltages of transistors (threshold voltage)), and the equivalent oxide thickness (EOT) of SiO₂ can be made thin.

Moreover, when forming the sidewall oxide films 111 conventionally, areas around end portions of the interface portion between the floating gate electrode 104 and the tunnel oxide film 102 are defectively oxidized, whereby oxidized regions 104a called “bird's beak” are formed, resulting in an increase of the film thickness. Further, at this time, phosphorus doped in the polysilicon generates, e.g., a phosphorus oxide (P₂O₅), causing a deterioration of the oxide film, which is one of causes of degradation of a memory maintenance function. In accordance with the embodiment of the present invention, however, by performing the plasma nitriding process, the nitrided region 103, which is formed at the surface portion of the tunnel oxide film 102 (interface portion between the tunnel oxide film 102 and the floating gate electrode 104), as shown in FIG. 93, functions as a barrier against the defective oxidation so that the oxidized regions 104a can be reduced considerably. As a result, the data maintenance function improves.

Moreover, since the dielectric constant can be increased by forming the nitrided region 103 at the surface portion of the tunnel oxide film 102 by means of nitriding it, the equivalent oxide thickness (EOT) of the oxide film (SiO₂) can be made thinner because the dielectric constant increases with the increase of an N dose even if the physical film thickness is same. As such, by forming the nitrided region the EOT can be reduced even if the physical film thickness remains same, so that an electron sustaining function improves, which in turn results in an improvement of the data maintenance function. This will be further explained with reference to FIG. 10. FIG. 10 is a diagram showing a relationship between a leakage current Jg (A/cm²) and an electric field E_{OX} (MV/cm) applied in a thickness direction, with respect to a base oxide film without being nitrided and cases where the nitriding process in accordance with the embodiment of the present invention is performed thereon while varying a dose of nitrogen atoms to 2.5×10¹⁵, 3.8×10¹⁵ and 5.2×10¹⁵ atoms/cm². Here, the dose of the nitrogen atoms was changed to 2.5×10¹⁵, 3.8×10¹⁵ and 5.2×10¹⁵ atoms/cm² by varying processing time to 40, 120 and 240 sec. respectively, by using the apparatus shown in FIG. 3 under the processing conditions of a chamber internal pressure of 126 Pa, a microwave power of 1600 W, an Ar flow rate of 1000 mL/min (sccm), and an N₂ flow rate of 40 mL/min (sccm). Further, the thickness of the base of the tunnel oxide film was 5 nm. As can be seen from the graph of this figure, the leakage current Jg rapidly increases regardless of the dose of the nitrogen atoms if the electric field E_{OX} exceeds 95 whereas, by performing the nitriding process, the leakage current Jg becomes smaller at a same electric field while the electric field E_{OX} becomes greater at a same leakage current Jg. If the dose of the nitrogen atoms increases, this tendency becomes stronger. Thus, it is confirmed that the electron sustaining function improves due to the increase of the EOT by forming the nitrided region, and this tendency becomes stronger as the dose of the nitrogen atoms increases.

FIG. 1 is a diagram showing a FN plot, with respect to a base oxide film without being nitrided and cases where the nitriding process in accordance with the embodiment of the present invention is performed thereon while varying a dose of nitrogen under the same conditions as those of FIG. 10. As can be seen from this diagram the slopes of graphs are same in both cases of performing or not performing the nitriding process. Thus, it is confirmed that there is no change in a barrier height even in case the nitriding process is performed. That is, the nitriding process does not affect an essential function of the device.

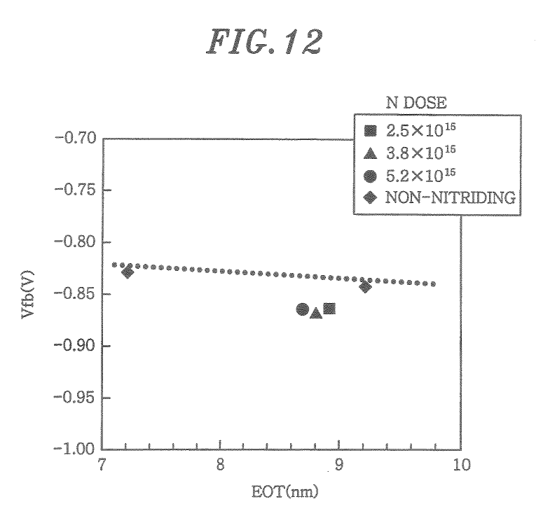

FIG. 12 is a diagram showing a relationship between a flat band voltage (Vfb) and an equivalent oxide thickness (EOT) of a tunnel oxide film with respect to a base oxide film without being nitrided and cases where the nitriding process in accordance with the embodiment of the present invention is performed thereon while varying a dose of nitrogen under the same conditions as those of FIG. 10. As can be seen from this diagram, the flat band voltage (Vfb hardly changes even when the nitriding process is performed. That is, by forming the nitrided region at the outermost surface portion of the tunnel oxide film ranging from the top surface thereof to the depth of about 2 nm therefrom, substantially no nitrogen is introduced to the interface portion, so that characteristics of the interface are not changed substantially.

As described above, by forming the nitrided region at the surface portion of the tunnel oxide film, the EOT can be reduced without changing the essential function of the device or the interface characteristics, whereby it is possible to improve the data maintenance function. Further, if the EOT is maintained same, the tunnel oxide film can be made thicker by the nitriding process, so that a leakage current can be suppressed as much as the thickness of the tunnel oxide film increases. As a result, the data maintenance characteristic can be improved as well.

Here, it is to be noted that the present invention can be modified in various ways without being limited to the embodiment described above. For example, though the plasma processing apparatus employed in the above embodiment is of a type that forms a high-density plasma at a low electron temperature by radiating a microwave into the chamber by means of the planar antenna having the plurality of slots, another plasma processing apparatus such as, e.g., an inductively coupled plasma processing apparatus, a planar reflective wave plasma processing apparatus, a magnetron plasma processing apparatus, or the like can be employed instead. Further, the structure of the non-volatile memory device and the manufacturing process thereof are not limited to those mentioned above. Moreover, though the Ar gas is used as the inert gas, another inert gas (He, Ne, Kr, Xe) can be used instead in the aspect of lowering the electron temperature of plasma, Ar gas, Kr gas and Xe gas are preferable and, particularly, the Ar gas is more preferable.

### INDUSTRIAL APPLICABILITY

The present invention contributes to the improvement of memory characteristics of nonvolatile memory devices such as an EPROM, an EEPROM, a flash memory and the like.

1-19. (canceled)

20: A method for nitriding a tunnel oxide film of a non-volatile memory device, comprising the steps of:
preparing a substrate having a tunnel oxide film;
generating a plasma including nitrogen gas on the substrate; and
forming a nitrided region at a surface portion of the tunnel oxide film by nitriding the tunnel oxide film with the plasma.

21: The method of claim 20, wherein the plasma processing is performed by using a plasma processing apparatus which generates a plasma by introducing a microwave into a processing chamber by a planar antenna including a plurality of slots.

22: The method of claim 20, wherein the processing gas includes a rare gas.

23: The method of claim 22, wherein a flow rate ratio between the rare gas and N₂ (rare gas/N₂ ratio) ranges from about 1.6 to 300.

24: The method of claim 23, wherein an N dose of the nitrided region is equal to or greater than about 1×10¹⁵ atoms/cm².

25: The method of claim 22, wherein the rare gas is Ar gas.

26: The method of claim 23, wherein the plasma processing is performed at a pressure of about 6.7 to 266 Pa.

27: The method of claim 24, wherein a high nitrogen concentration region is formed at an outermost surface portion of the tunnel oxide film ranging from its top surface to a depth of about 2 nm therefrom.

28: The method of claim 21, wherein when the plasma is generated, the plasma is ignited at a higher pressure than the pressure in the nitriding processing.

29: The method of claim 28, wherein the pressure ranges from about 13.3 to 267 Pa.

30: The method of claim 23, wherein the nitriding processing is performed at a temperature of about 200 to 600° C.

31: The method of claim 21, wherein the planar antenna is a radial line slot antenna.

32: A method for manufacturing a non-volatile memory device, comprising the steps of:
forming a tunnel oxide film on a silicon substrate;
generating a plasma including nitrogen gas on the substrate;
forming a nitrided region at a surface portion of the tunnel oxide film by nitriding the tunnel oxide film with the plasma;
forming a floating gate on the tunnel oxide film;
forming a dielectric film on the floating gate;
forming a control gate on the dielectric film; and
forming a sidewall oxide film on a sidewall of each of the floating gate and the control gate.

33: The method of claim 32, wherein the plasma processing is performed by using a plasma processing apparatus which generates a plasma by introducing a microwave into a processing chamber by a planar antenna including a plurality of slots.

34: The method of claim 32, wherein an N dose of the nitrided region is equal to or greater than about 1×10¹⁵ atoms/cm².

35: The method of claim 34, wherein a high nitrogen concentration region is formed at an outermost surface portion of the tunnel oxide film ranging from its top surface to a depth of about 2 nm therefrom.

36: A non-volatile memory device comprising:
a silicon substrate;
a tunnel oxide film formed on the silicon substrate;
a floating gate formed on the tunnel oxide film;
a dielectric film formed on the floating gate;
a control gate formed on the dielectric film; and
sidewall oxide films formed on sidewalls of the floating gate and the control gate,
wherein a nitrided region is formed at a surface portion of the tunnel oxide film by nitriding the tunnel oxide film with a plasma including nitrogen gas.

37: The non-volatile memory device of claim 36, wherein the nitrided region is formed by using a plasma processing apparatus which generates a plasma by introducing a microwave into a processing chamber by a planar antenna including a plurality of slots.

38: The non-volatile memory device of claim 36, wherein an N dose of the nitrided region is equal to or greater than about 1×10¹⁵ atoms/cm².

39: The non-volatile memory device of claim 38 wherein a high nitrogen concentration region is formed at an outermost surface portion of the tunnel oxide film ranging from its top surface to a depth of about 2 nm therefrom.
